(19) United States
(12) Patent Application Publication
(10) Pub. No.: US 2023/0387568 A1
(43) Pub. Date: Nov. 30, 2023

(54) CIRCUIT BOARD FOR ANTENNA, ANTENNA PACKAGE INCLUDING THE SAME AND IMAGE DISPLAY DEVICE INCLUDING THE SAME

(71) Applicant: DONGWOO FINE-CHEM CO., LTD., Jeollabuk-do (KR)

(72) Inventors: Sung Hoe KIM, Seoul (KR); Na Yeon KIM, Seoul (KR); Dae Kyu KIM, Gyeonggi-do (KR)

(21) Appl. No.: 18/201,231

(22) Filed: May 24, 2023

(30) Foreign Application Priority Data
May 27, 2022 (KR) 10-2022-0065518

(51) Int. Cl. H01Q 1/22; H01Q 1/38; H01Q 1/14; H01Q 1/40

(52) U.S. Cl. CPC H01Q 1/22; H01Q 1/38; H01Q 1/14; H01Q 1/40

(57) ABSTRACT

A circuit board for an antenna includes a core layer having a first surface and a second surface facing each other, a signal wiring disposed on the first surface of the core layer, and a conductive layer disposed on the second surface of the core layer to cover the signal wiring in a plan view. The conductive layer has a slit portion formed around the signal wiring in the plan view.

### CROSS-REFERENCE TO RELATED APPLICATION AND CLAIM OF PRIORITY

This application claims the benefit under 35 USC §119 of Korean Patent Application No. 10-2022-0065518 filed on May 27, 2022, in the Korean Intellectual Property Office (KIPO), the entire disclosures of which is incorporated herein by reference for all purposes.

### BACKGROUND

### 1. Field

The present invention relates to a circuit board for an antenna, an antenna package including the same and an image display device including the same. More particularly, the present invention relates to a circuit board for an antenna including a feeding circuit wiring, an antenna package including the same and an image display device including the same.

### 2. Description of the Related Art

As information technologies have been developed, a wireless communication technology such as Wi-Fi, Bluetooth, etc., is combined with an image display device in, e.g., a smartphone form. In this case, an antenna may be combined with the image display device to provide a communication function.

Recently, as mobile communication technologies has been developed, an antenna for a communication in a high frequency or an ultra-high frequency band is needed in the image display device.

To increase sensitivity and gain of a radiator included in an antenna, the radiator may be disposed within a display area of a front side in the image display device. Additionally, a length of a transmission line connected to the radiator and disposed in a bezel area may be reduced so as to reduce a signal loss transmitted to the radiator.

In this case, the radiator may be adjacent to the bezel area where a circuit connection is implemented. Accordingly, antenna radiation properties from the radiator may be disturbed by an electrical interference in the bezel area.

Further, as a frequency band of the antenna is shifted to, e.g., the high frequency or ultra-high frequency band of 20 GHz or more, a signal/frequency disturbance may occur even by a small electrical interference and external noise.

### SUMMARY

According to an aspect of the present invention, there is provided a circuit board for an antenna providing improved radiation property and electrical reliability.

According to an aspect of the present invention, there is provided an antenna package including a circuit board for an antenna that provides improved radiation property and electrical reliability.

According to an aspect of the present invention, there is provided an image display device including the antenna package.

(1) A circuit board for an antenna, including: a core layer having a first surface and a second surface facing each other; a signal wiring disposed on the first surface of the core layer; and a conductive layer disposed on the second surface of the core layer to cover the signal wiring in a plan view, the conductive layer having a slit portion formed around the signal wiring in the plan view.

(2) The circuit board for an antenna according to the above (1), wherein the slit portion includes a pair of slit portions formed at both lateral sides of a front end portion of the signal wiring in the plan view.

(3) The circuit board for an antenna according to the above (2), wherein the conductive layer includes a feeding ground portion disposed between the pair of slit portions to cover the front end portion of the signal wiring in the plan view.

(4) The circuit board for an antenna according to the above (3), wherein a ratio of a width of the feeding ground portion to a line width of the signal wiring is from 10 to 18.

(5) The circuit board for an antenna according to the above (3), wherein a ratio of a width of the feeding ground portion to a width of the slit portion is from 0.8 to 2.

(6) The circuit board for an antenna according to the above (3), wherein the conductive layer has a first portion including the slit portion and the feeding ground portion, and a second portion having a solid plate shape.

(7) The circuit board for an antenna according to the above (6), wherein the second portion covers a rear end portion of the signal wiring in the plan view.

(8) The circuit board for an antenna according to the above (2), wherein a plurality of the slit portions are formed at each of both lateral sides of the front end portion of the signal wiring in the plan view.

(9) The circuit board for an antenna according to the above (1), wherein the signal wiring includes a plurality of signal wirings arranged in a width direction, and the slit portion is formed between the plurality of signal wirings.

(10) The circuit board for an antenna according to the above (9), wherein a plurality of the slit portions are formed between a pair of adjacent signal wirings among the plurality of signal wirings.

(11) The circuit board for an antenna according to claim 1, wherein the signal wiring includes a plurality of feeding portions and a merging portion coupling the feeding portions to each other, and the slit portion is formed in each region between the feeding portions in the plan view.

(12) An antenna package, including: an antenna unit including a radiator and a transmission line connected to the radiator; and the circuit board for an antenna of the above-described embodiments electrically connected to the antenna unit.

(13) The antenna package according to the above (12), wherein the antenna unit further includes a signal pad connected to an end portion of the transmission line, a front end portion of the signal wiring of the circuit board for an antenna is bonded to the signal pad, and the slit portion is formed around the front end portion of the signal wiring.

(14) The antenna package according to the above (13), wherein the radiator has a mesh structure, and the signal pad has a solid structure.

(15) An image display device, including: a display panel; an antenna unit disposed on the display panel; and the circuit board for an antenna of the above-described embodiments electrically connected to the antenna unit.

(16) The image display device according to the above (15), wherein a rear end portion without the slit portion of the circuit board for an antenna is bent below the display panel.

A circuit board for an antenna according to embodiments of the present invention may include a ground layer and a signal wiring formed on a first surface and a second surface of a core layer, respectively. A feeding efficiency through the signal wiring may be improved by an electric field formed between the ground layer and the signal wiring. Additionally, noises around the signal wiring may be absorbed or blocked by the ground layer, so that a feeding loss to the antenna may be prevented.

In example embodiments, the ground layer may include a slit portion formed around a feeding portion of the signal wiring. A transmission path of a nearby noise may be increased through the slit portion, thereby increasing a signal concentration around the feeding portion and increasing an antenna gain. Further, a coupling and an electric field interference generated between metal layers of the circuit board and the antenna device in a bonding region coupled to the antenna device may be reduced or suppressed.

In example embodiments, the ground layer may include a first portion including the slit portion and a second portion having a solid plate shape. An efficiency of receiving power from a driving circuit chip may be increased through the second portion, and reliability of an antenna feeding may be enhanced through the first portion, thereby improving overall antenna radiation reliability and gain.

### BRIEF DESCRIPTION OF THE DRAWINGS

FIG. 1 is a schematic cross-sectional view illustrating a circuit board for an antenna in accordance with exemplary embodiments.

FIGS. 2 and 3 are schematic plan views illustrating a circuit board for an antenna in accordance with exemplary embodiments.

FIG. 4 is a schematic plan view illustrating a circuit board for an antenna in accordance with exemplary embodiments.

FIGS. 5 and 6 are schematic plan views illustrating a circuit board for an antenna in accordance with exemplary embodiments.

FIG. 7 is a schematic plan view illustrating an antenna device in accordance with exemplary embodiments.

FIG. 8 is a schematic plan view illustrating an antenna package in accordance with exemplary embodiments.

FIGS. 9 and 10 are schematic plan views illustrating an antenna package and an antenna circuit board, respectively, in accordance with exemplary embodiments.

FIGS. 11 and 12 are schematic cross-sectional and plan views, respectively, illustrating an image display device including an antenna package according to exemplary embodiments.

FIG. 13 is a graph showing a change of an antenna gain according to a change of a width of a feeding ground portion.

FIGS. 14A to 14C are graphs showing changes of an antenna gain according to modification of a slit portion.

### DETAILED DESCRIPTION OF THE EMBODIMENTS

According to embodiments of the present invention, a circuit board for an antenna including a ground and a signal wiring is provided. Additionally, an antenna package and an image display device including the antenna circuit board are provided.

In exemplary embodiments, a radiator of the antenna package may be disposed in a display area of the image display device. Accordingly, the antenna package may be provided as an antenna package for an AOD (Antenna-On Display).

In some embodiments, the circuit board for an antenna may be manufactured in the form of a microstrip line (MSL)-type board, and the antenna package may be fabricated in the form of a microstrip patch combined with an antenna device.

The antenna device or the antenna package may be applied to a communication device for, e.g., 3G, 4G, 5G or higher high-frequency or ultra-high frequency mobile communication.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

The terms “first”, “second”, “upper”, “lower”, “top”, “bottom”, etc., used herein do not designate an absolute position, but are relatively used to distinguish different elements or different positions.

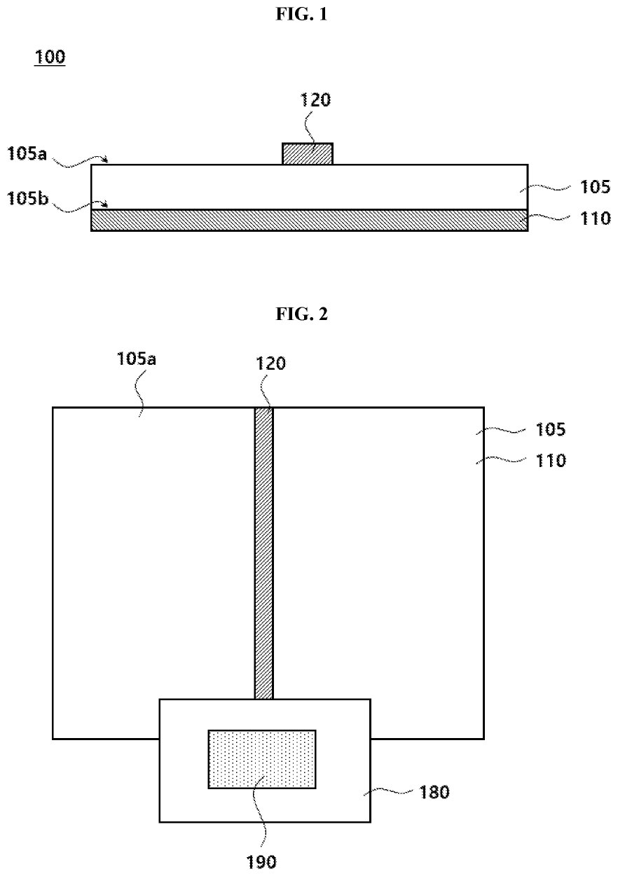

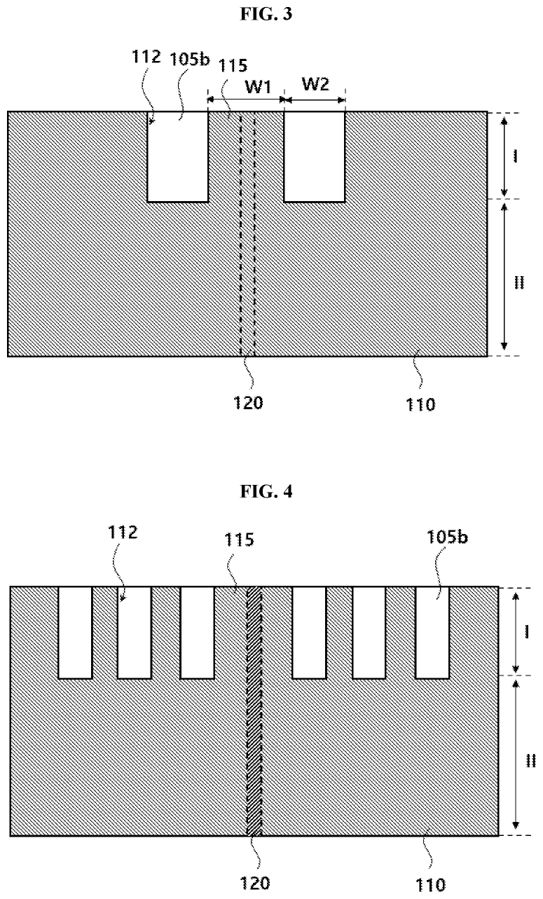

FIG. 1 is a schematic cross-sectional view illustrating a circuit board for an antenna in accordance with exemplary embodiments. FIGS. 2 and 3 are schematic plan views illustrating a circuit board for an antenna in accordance with exemplary embodiments.

For example, FIGS. 2 and 3 are plan views from a first surface 105a and a second surface 105b of a core layer 105, respectively.

Referring to FIG. 1, a circuit board 100 for an antenna (hereinafter, that may be abbreviated as a circuit board) may include the core layer 105, a conductive layer 110 and a signal wiring 120. In exemplary embodiments, the circuit board 100 may be provided as a MSL-type flexible printed circuit board (FPCB).

The core layer 105 may serve as an insulating substrate of the circuit board 100. For example, the core layer 105 may include a flexible resin such as a polyimide resin, modified polyimide (MPI), an epoxy resin, polyester, a cyclo olefin polymer (COP), a liquid crystal polymer (LCP), etc. The core layer 105 may include an internal insulating layer included in the circuit board 100.

The core layer 105 may include the first surface 105a and the second surface 105b. The first surface 105a and the second surface 105b may face each other and may correspond to top and bottom surfaces of the core layer 105, respectively.

In exemplary embodiments, the first surface 105a of the core layer 105 may provide an adhering surface or a bonding surface with the antenna device.

The conductive layer 110 and the signal wiring 120 may be disposed on the second surface 105b and the first surface 105a of the core layer 105, respectively. The conductive layer 110 may overlap the signal wiring 120 in a plan view.

The conductive layer 110 and the signal wiring 120 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca), or an alloy containing at least one of the metals. These may be used alone or in combination of two or more therefrom.

For example, each of the conductive layer 110 and the signal wiring 120 may include copper or a copper alloy.

Referring to FIG. 2, the signal wiring 120 may be disposed on the first surface 105a of the core layer 105.

The signal wiring 112 may serve as a feeding/signal transfer wiring to an antenna device. A terminal end portion of the signal wiring 120 may be connected to an antenna driving integrated circuit (IC) chip 190 to receive feeding and control signals for driving the antenna.

In some embodiments, the terminal end portion of the signal wiring 120 may be coupled to a connector (not illustrated). The circuit board 100 may be coupled to a chip mounting board 180 through the connector. The antenna driving IC chip 190 may be mounted on the chip mounting substrate 180 and electrically connected to the signal wiring 120 through the connector.

In some embodiments, the circuit board 100 may include a flexible printed circuit board (FPCB), and the chip mounting board 180 may include a rigid printed circuit board (Rigid-PCB).

A front end portion of the signal wiring 112 may serve as a feeding portion electrically connected to the antenna device. Accordingly, the feeding and control signals input from the antenna driving IC chip 190 may be transferred to the antenna device through the signal wiring 120. For example, the feeding portion may be bonded to the antenna device.

Referring to FIG. 3, the conductive layer 110 may be disposed on the second surface 105b of the core layer 105. As indicated by a dotted line in FIG. 3, when projected in a plan view, the conductive layer 110 may cover the signal wiring 120. In some embodiments, the conductive layer 110 may entirely cover the signal wiring 120 in the plan view. In example embodiments, the conductive layer 110 may serve as a ground of the signal wiring 120.

The conductive layer 110 may include a first portion I and a second portion II. In example embodiments, the first portion I may include the slit portion 112.

The slit portion 112 may be formed by etching a portion of the conductive layer 110 adjacent to the front end portion or the feeding portion of the signal wiring 120 in the plan view. The slit portion 112 has a recess shape, and the second surface 105b of the core layer 105 may be exposed through the slit portion 112.

In example embodiments, a pair of the slit portions 112 may be formed to face each other with the front end portion or the feeding portion of the signal wiring 120 interposed therebetween. For example, the first portion I of the conductive layer 110 may include a feeding ground portion 115 formed between the pair of the slit portions 112.

The feeding ground portion 115 may cover the front end portion or the feeding portion of the signal wiring 120 in a plan view. The slit portion 112 may be horizontally spaced apart from the signal wiring 120 by the feeding ground portion 115 in the plan view.

The second portion II of the conductive layer 110 may have a solid plate or conductive film shape. For example, the second portion II may be a solid layer without a vacancy such as a slit, a recess, a hole or an opening therein.

The second portion II of the conductive layer 110 may cover a rear end portion of the signal wiring 120 in the plan view.

According to exemplary embodiments as described above, the conductive layer 110 overlapping the signal wiring 120 in a thickness direction may be formed, so that a feeding rate and efficiency through the signal wiring 120 may be enhanced by the formation of an electric field in the core layer 105.

The slit portion 112 may be formed around the feeding portion of the signal wiring 120 bonded to the antenna device to increase a moving distance of a noise in the bonding region where the noise may be concentrated. For example, the noise may be bypassed along a profile of the slit portion 112 to reduce or suppress signal interference and frequency disturbance to the feeding portion.

Additionally, the amount of the conductive layer or conductive material in the bonding region with the antenna device may be reduced by the slit portion 112, and a coupling of the conductive layers generated in the bonding region may be reduced or suppressed.

A width W1 of the feeding ground portion 115 and a width W2 of the slit portion 112 may be adjusted in consideration of the feeding promotion of the signal wiring 120 and the noise bypass.

In some embodiments, a ratio of the width W1 of the feeding ground portion 115 relative to a line width of the signal wiring 120 may be from 10 to 18, preferably from 10 to 16, and more preferably from 10 to 14.

In one embodiment, a ratio (W2/W1) of the width W2 of the slit portion 112 to the width W1 of the feeding ground portion 115 may be from 0.8 to 2, preferably from to 2, more preferably from 1 to 1.5.

Within this range, noise attenuation and antenna gain increase through the slit portion 112 may be sufficiently implemented while maintaining feeding efficiency through the feeding ground portion 115.

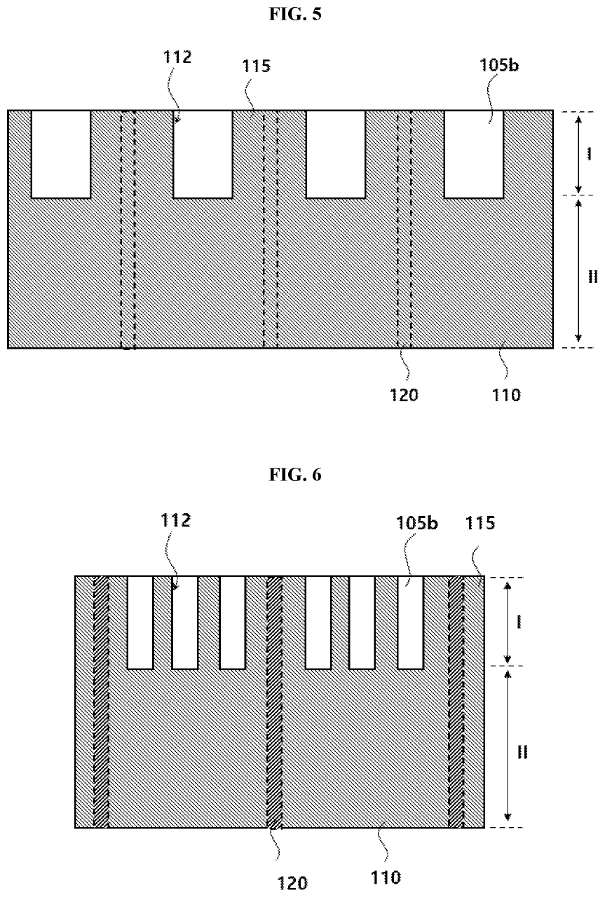

FIG. 4 is a schematic plan view illustrating a circuit board for an antenna in accordance with exemplary embodiments.

Referring to FIG. 4, a plurality of slit portions 112 may be formed at both lateral sides of the feeding ground portion 115 or the signal wiring 120.

For example, a slit row including at least two or more slit portions 112 may be formed at one lateral side of the feeding ground portion 115 or the signal wiring 120 in the width direction. The slit row including at least two or more slit portions 112 may also be formed at the other lateral side of the feeding ground portion 115 or the signal wiring 120 in the width direction.

Accordingly, a pair of the slit rows may be arranged with the feeding ground portion 115 or the signal wiring 120 interposed therebetween in the plan view.

A plurality of the slit portions 112 may be arranged in an array form, so that the bypass path of the noise may be additionally increased, and signal interference to the signal wiring 120 may be effectively reduced or blocked.

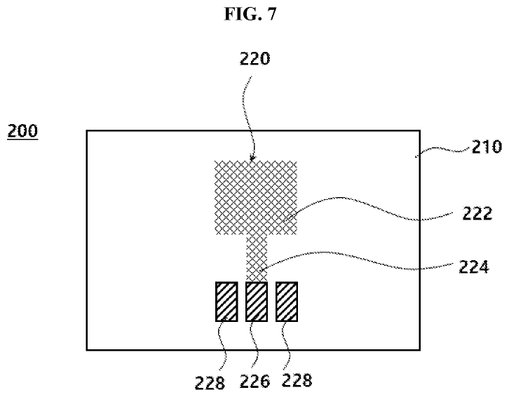

FIGS. 5 and 6 are schematic plan views illustrating a circuit board for an antenna in accordance with exemplary embodiments.

Referring to FIG. 5, a plurality of the signal wirings 120 may be arranged on the first surface 105a of the core layer 105. As indicated by dotted lines in FIG. 5, the plurality of the signal wirings 120 may extend to be substantially parallel to each other and arranged in the width direction.

In some embodiments, each of the signal wirings 120 may serve as an independent feeding wiring, and may be individually connected to an antenna unit of the antenna device.

As described above, the slit portions 112 may be formed at both lateral sides of one signal wiring 120 in the plan view. Further, one slit portion 112 may be disposed between the signal wirings 120 neighboring in the plan view.

Referring to FIG. 6, as described with reference to FIG. 4, the slit row including a plurality of the slit portions 112 may be arranged at both sides of one signal wiring 120 in the plan view. As described with reference to FIG. 5, a plurality of the signal wirings 120 may be arranged on the first surface 105a of the core layer 105 along the width direction.

Accordingly, the slit row including the plurality of the slit portions 112 may be disposed between neighboring signal wirings 120.

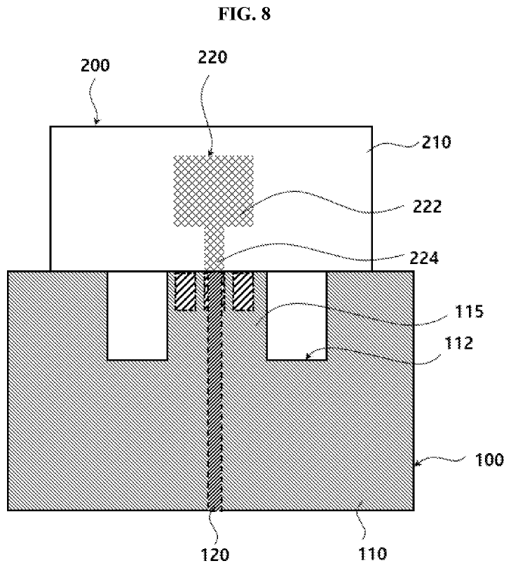

FIG. 7 is a schematic plan view illustrating an antenna device in accordance with exemplary embodiments.

Referring to FIG. 7, the antenna device 200 may include an antenna unit 220 disposed on a dielectric layer 210.

The antenna unit 220 may include a radiator 222 and a transmission line 224. In some embodiments, the radiator 222 may have a polygonal plate shape and may have a mesh structure. Accordingly, the radiator 222 has improved transmittance and may be disposed within a display area of an image display device.

The transmission line 224 may be integrally connected to the radiator 222 and may be electrically connected to the feeding portion (or the front end portion) of the signal wiring 120 of the circuit board 100. In some embodiments, an end portion of the transmission line 224 and the feeding portion of the signal wiring 120 may be bonded to each other using an anisotropic conductive film (ACF).

The transmission line 224 may have a mesh structure substantially the same as or similar to that of the radiator 222. In some embodiments, the transmission line 224 may be disposed at least partially within a bezel area or a non-display area of the image display device. In this case, the transmission line 224 may be formed as a solid line to provide reduced resistance and increased signal speed.

The transmission line 224 may be formed as a single member substantially integral with the radiator 222 and may have a smaller width than that of the radiator 222. The antenna unit 220 may further include a signal pad 226. The signal pad 226

may be connected to one end portion of the transmission line 224. In an embodiment, the signal pad 226 may be formed as a substantially integral member with the transmission line 224, and a terminal end portion of the transmission line 224 may serve as the signal pad 226.

In some embodiments, a ground pad 228 may be disposed around the signal pad 226. For example, a pair of the ground pads 228 may face each other with the signal pad 226 interposed therebetween.

For example, the ground pad 228 may be electrically and physically separated from the transmission line 224 around the signal pad 226. The ground pad 228 may be provided as a bonding pad to improve a bonding stability with the ACF.

The signal pad 226 and the ground pad 228 may be solid patterns formed of the above-described metal or alloy in consideration of the reduction of feeding resistance and noise absorption efficiency.

In example embodiments, one radiator 222 may be connected to one corresponding transmission line 224 or one corresponding signal pad 226.

In example embodiments, the antenna unit 220 or the radiator 222 may be designed to transmit and receive signals in a high frequency or ultra-high frequency (e.g., 3G, 4G, 5G or higher) band. For example, a resonance frequency of the antenna unit 220 or the radiator 222 may be 10 GHz or more, from 10 GHz to 70 GHz, preferably from 20 GHz to 70 GHz. In one embodiment, the resonance frequency of the antenna unit 220 may be about 28 GHz or more, about 35 GHz or more, or from 36 GHz to 40 GHz. In one embodiment, the resonance frequency of the antenna unit 220 may be about 50 GHz or higher, for example, from about 50 GHz to 70 GHz.

The antenna unit 220 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca) or an alloy containing at least one of the metals. These may be used alone or in a combination of at least two therefrom.

In an embodiment, the antenna unit 220 may include silver (Ag) or a silver alloy (e.g., silver-palladium-copper (APC)), or copper (Cu) or a copper alloy (e.g., a copper-calcium (CuCa)) to implement a low resistance and a fine line width pattern.

In some embodiments, the antenna unit 220 or the radiator 222 may include a transparent conductive oxide such as indium tin oxide (ITO), indium zinc oxide (IZO), indium zinc tin oxide (ITZO), zinc oxide (ZnOx), etc.

In some embodiments, the antenna unit 220 or the radiator 222 may include a stacked structure of a transparent conductive oxide layer and a metal layer. For example, the antenna unit may include a double-layered structure of a transparent conductive oxide layer-metal layer, or a triple-layered structure of a transparent conductive oxide layer-metal layer-transparent conductive oxide layer. In this case, flexible property may be improved by the metal layer, and a signal transmission speed may also be improved by a low resistance of the metal layer. Corrosive resistance and transparency may be improved by the transparent conductive oxide layer.

The radiator 222 may include a blackened portion, so that a reflectance at a surface of the radiator 222 may be decreased to suppress a visual pattern recognition due to a light reflectance.

In an embodiment, a surface of the metal layer included in the antenna unit 220 may be converted into a metal oxide or a metal sulfide to form a blackened layer. In an embodiment, a blackened layer such as a black material coating layer or a plating layer may be formed on the antenna unit 220 the metal layer. The black material or plating layer may include silicon, carbon, copper, molybdenum, tin, chromium, molybdenum, nickel, cobalt, or an oxide, sulfide or alloy containing at least one therefrom.

A composition and a thickness of the blackened layer may be adjusted in consideration of a reflectance reduction effect and an antenna radiation property.

In some embodiments, a dummy mesh electrode (not illustrated) may be formed around the radiator 222.

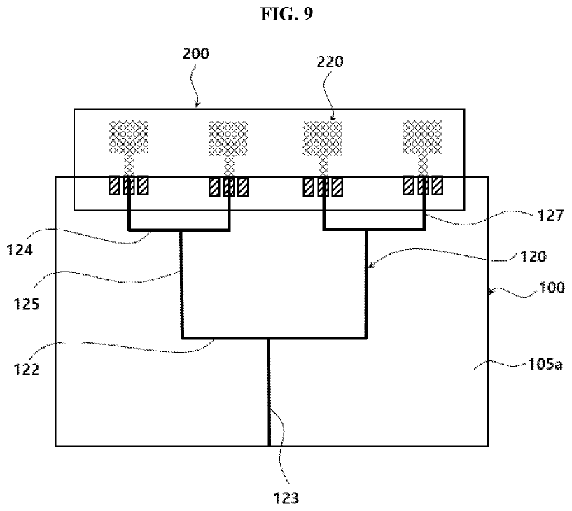

FIG. 8 is a schematic plan view illustrating an antenna package in accordance with exemplary embodiments.

Referring to FIG. 8, the antenna device 200 and the circuit board 100 may be electrically connected to form an antenna package.

For example, an ACF may be attached on the dielectric layer 210 to cover the signal pad 226 and the ground pads 228. Thereafter, the front end portion of the signal wiring 120 of the circuit board 100 may be aligned on the signal pad 226 of the antenna unit 220, and then heated and compressed. Accordingly, the signal wiring 120 and the signal pad 226 may be electrically connected through the ACF.

As illustrated in FIG. 8, the conductive layer 110 may be formed on the second surface 105b of the circuit board 100, and the slit portion 112 may be formed around the bonding region of the signal pad 226 and the signal wiring 120.

In the bonding region, the slit portion 112 may serve as a horizontal barrier of noise, and a feeding concentration may be increased and a signal loss may be reduced by the feeding ground portion 115.

Although one antenna unit 220 is illustrated in the antenna device 200 in FIG. 8, a plurality of antenna units 220 may be arranged along the width direction to form an antenna array.

In this case, as described with reference to FIG. 5 or 6 the circuit board 100 may include a plurality of the signal wirings 120 connected to the signal pad 226 of each antenna unit 220. Accordingly, an active-type antenna package in which independent radiation and driving control can be implemented from each antenna unit 220 may be provided.

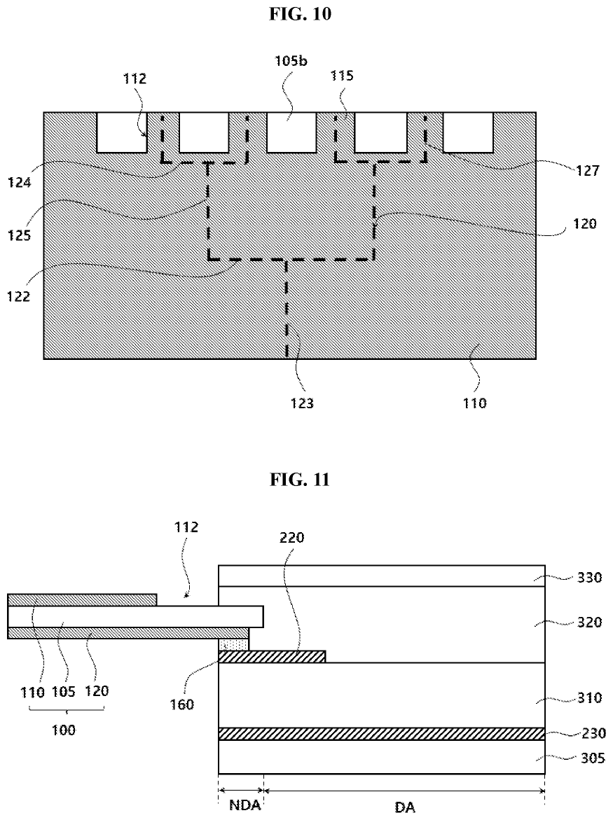

FIGS. 9 and 10 are schematic plan views illustrating an antenna package and an antenna circuit board, respectively, in accordance with exemplary embodiments.

Referring to FIG. 9, a plurality of the antenna units 220 may be connected by the signal wiring 120 of the circuit board 100 to form a radiation group. For example, as illustrated in FIG. 9, four antenna units 220 may be coupled to form one radiation group. Accordingly, a passive-type antenna package in which a plurality of the antenna units 220 are fed/driven together through one signal wiring 120 may be provided.

For example, the signal wiring 120 may include an external circuit connecting portion 123, a first merging portion 122, a branch portion 125, a second merging portion 124, and a feeding portion 127 sequentially from a terminal end portion to a front end portion thereof.

One end of the external circuit connecting portion 123 may be a portion adjacent to and electrically connected to the antenna driving IC chip 190. The first merging portion 122 may horizontally extend to be connected to the other end of the external circuit connecting portion 123, and the branch portions 125 (e.g., a pair of branch portions 125) may extend toward the antenna unit 220.

The second merging portion 124 extending horizontally may be connected to each end of the branch portion 125, and the feeding portions 127 (e.g., a pair of the feeding portions) may extend from each second merging portion 124 toward the antenna unit 220. Each feeding portion 127 may be bonded with one antenna unit 220.

Referring to FIG. 10, the conductive layer 110 may be disposed on the second surface 105b of the core layer 105, and may cover the signal wiring 120 indicated by dotted lines as described above with reference to FIG. 9 in the plan view.

The slit portions 112 may be formed at both lateral sides of one feeding portion 127. Additionally, the slit portion 112 may be formed between neighboring feeding portions 127. The neighboring slit portions 112 may face each other with the feeding ground portion 115 interposed therebetween, and the feeding ground portion 115 may cover each of the feeding portions 127 in the plan view.

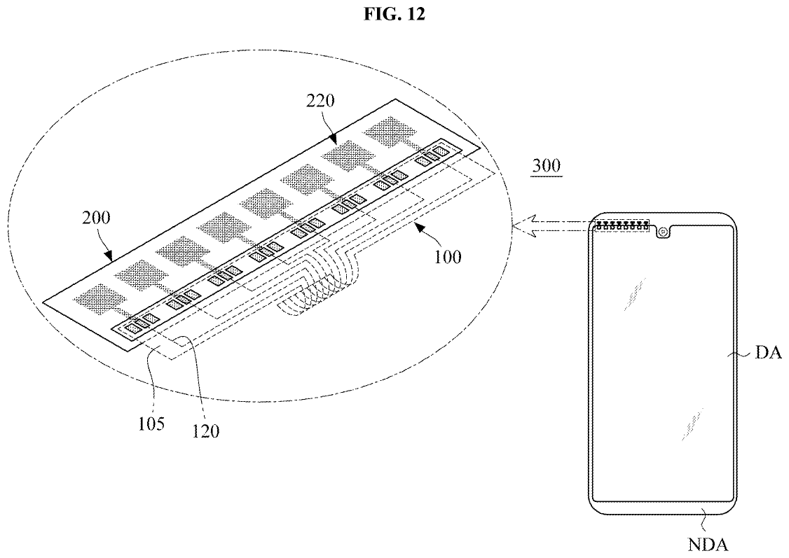

FIGS. 11 and 12 are schematic cross-sectional and plan views, respectively, illustrating an image display device including an antenna package according to exemplary embodiments.

For example, FIG. 12 shows a front portion or a window surface of an image display device implemented in the form of a smart phone. For convenience of descriptions, the conductive layer 110 of the circuit board 100 is omitted and only the core layer 105 and the signal wiring 120 of the circuit board 100 are illustrated in FIG. 12.

Referring to FIGS. 11 and 12, the image display device 300 may include a display area DA and a non-display area NDA. The non-display area NDA may be disposed at both end portions or both lateral sides of the display area DA, and may include a peripheral portion of the image display device 300.

For example, the non-display area NDA may include a bezel area and may include the bonding region of the antenna package.

The image display device 300 may include a display panel 305, and the antenna package in which the antenna device including the antenna unit 220 and the circuit board 100 are combined may be disposed on the display panel 305.

The display panel 305 may include a TFT array substrate and a pixel structure including an OLED display layer or a liquid crystal display layer disposed on the TFT array substrate.

A first dielectric layer 310 may be stacked on the display panel 305. The first dielectric layer 310 may include, e.g., the, a dielectric layer 210 for driving the antenna unit 220.

The first dielectric layer 310 may include, e.g., a transparent resin material. For example, the first dielectric layer 310 may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more thereof.

In some embodiments, the first dielectric layer 310 may include an adhesive material such as an optically clear adhesive (OCA), an optically clear resin (OCR), or the like.

In some embodiments, the first dielectric layer 310 may include an inorganic insulating material such as glass, silicon oxide, silicon nitride, silicon oxynitride, etc.

In an embodiment, the first dielectric layer 310 may be provided as a substantially single layer. In an embodiment, the first dielectric layer 310 may include a multi-layered structure of at least two layers.

In some embodiments, a dielectric constant of the first dielectric layer 310 may be adjusted in a range from about 1.5 to about 12. If the dielectric constant exceeds about 12, a driving frequency may be excessively decreased, and driving in a desired high frequency or ultrahigh frequency band may not be implemented.

In some embodiments, an antenna ground layer 230 overlapping the antenna unit 210 in a thickness direction may be disposed on a bottom surface of the first dielectric layer 310. A vertical radiation from the radiator 222 toward a front surface of the image display device 300 may be substantially implemented by the antenna ground layer 230.

The antenna ground layer 230 may include the above-described metal and/or alloy. In some embodiments, the antenna device 200 may be defined by the antenna ground layer 230, the first dielectric layer 310 and the antenna unit 220.

In some embodiments, a conductive member of the image display device 300 to which the antenna package is applied may serve as the antenna ground layer 230. For example, the conductive member may include various electrodes or wirings such as, e.g., a gate electrode, a source/drain electrode, a pixel electrode, a common electrode, a scan line, a data line, etc., included in a thin film transistor (TFT) array of a display panel.

In one embodiment, various structures including a conductive material disposed under the display panel 305 may serve as the antenna ground layer. For example, a metallic plate (e.g., a stainless steel plate such as a SUS plate), a pressure sensor, a fingerprint sensor, an electromagnetic wave shielding layer, a heat dissipation sheet, a digitizer, etc., may serve as the antenna ground layer.

The circuit board 100 may be electrically connected to the antenna unit 220 through a conductive intermediate structure 160. The conductive intermediate structure 160 may include an anisotropic conductive film (ACF).

For example, the conductive intermediate structure 160 may be attached to the signal pad 226 of the antenna unit 220 on the bonding region. Thereafter, the terminal end portion of the signal wiring 120 of the circuit board 100 may be aligned on the conductive intermediate structure 160, and then the circuit board 100 and the antenna unit 220 may be coupled through a heat compression.

The image display device 300 or the antenna device may include a second dielectric layer 320 covering the antenna unit 220. The second dielectric layer 320 may also cover the circuit board 100 in the bonding region.

A cover window 330 may be disposed on the second dielectric layer 320. The cover window 330 may include a hard coating film or glass (e.g., UTG).

As illustrated in FIG. 12, a rear end portion of the circuit board 100 of the antenna package may be bent and electrically connected to the antenna driving IC chip 190 disposed under the display panel 305.

As described above, the antenna driving IC chip 190 may be mounted on a chip mounting board (e.g., a main board or rigid PCB) 180, and may be electrically connected to the circuit board 100 and the antenna unit 220 through a connector.

As illustrated in FIG. 12, the radiator 222 may have a mesh structure and may be disposed to be adjacent to the non-display area NDA or the bonding region. Accordingly, the gain and frequency properties of the radiator 222 may be deteriorated due to the coupling between the conductive layer included in the circuit board 100 and the conductive structure included in the antenna device or the display panel 305 that may occur in the bonding region

However, according to the above-described exemplary embodiments, the area of the conductive layer disposed in the bonding region may be reduced by the formation of the slit portion 112, so that the coupling may be suppressed while implementing grounding properties for s signal efficiency transmitted to the antenna unit 220.

Additionally, a current flow path in the conductive layer may be increased through the slit portion 112 to reduce the signal loss due to noises and increase the antenna gain.

Hereinafter, preferred embodiments are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### Experimental Example 1

### Measurement of Antenna Gain According to Ratio of Width of Feeding Ground to Width of Signal Wiring

A circuit board for an antenna having the structure illustrated in FIGS. 1 to 3 was manufactured. A width of the signal wiring 120 was fixed at 0.115 mm, and a plurality of samples were manufactured by changing the width of the feeding ground portion 115 of the conductive layer 110. Slits of 2 mm were formed on both lateral sides of the feeding ground portion 115 of each sample.

While supplying a power through a terminal end of the signal wiring 120, an antenna gain value according to a frequency was extracted in a radiation chamber.

A ratio of the width of the feeding ground portion 115 to the width of the signal wiring 120 (0.115 mm) of each sample is shown in Table 1 below.

TABLE 1

| | width of feeding ground portion | ratio relative to width of |
|---|---|---|
| No. | (mm) | signal wiring |
| Sample 1-1 | 1 | 8.7 |
| Sample 1-2 | 1.2 | 10.4 |
| Sample 1-3 | 1.4 | 12.2 |
| Sample 1-4 | 1.6 | 13.9 |
| Sample 1-5 | 1.8 | 15.7 |
| Sample 1-6 | 2.0 | 17.4 |
| Sample 1-7 | 2.2 | 19.1 |

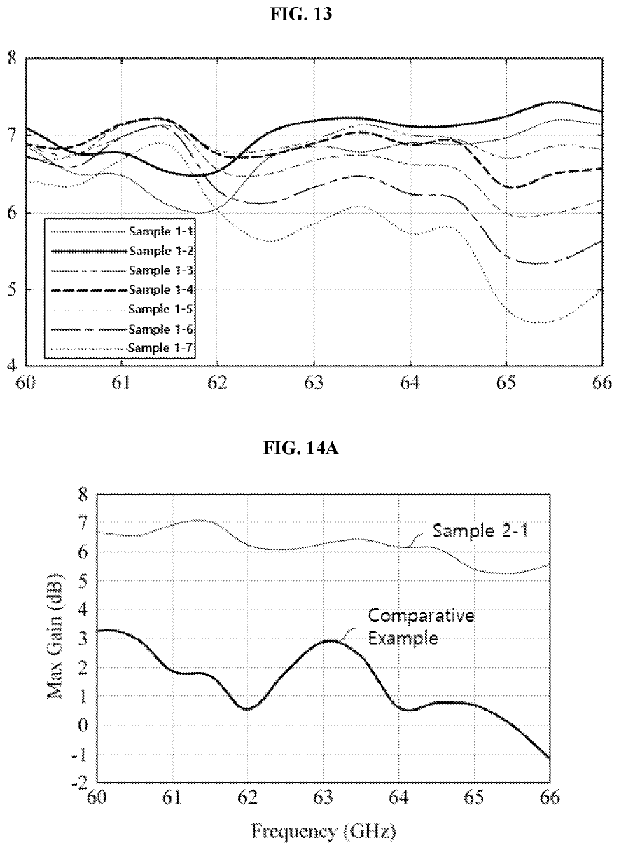

FIG. 13 is a graph showing a change of an antenna gain according to a change of a width of a feeding ground portion.

Referring to FIG. 13, stable gain values were generally maintained in a range of to 66 GHz when the ratio of the width of the feeding ground to the width of the signal wiring was in the range of about 10 to 18, preferably from 10 to 16.

### Experimental Example 2

### Measurement of Antenna Gain According to Slit Modification

A circuit board for an antenna having the structure illustrated in FIGS. 1 to 3 was manufactured. The width of the signal wire 120 was 0.115 mm, and the width of the feeding ground portion 115 of the conductive layer 110 was 1.6 mm.

In Sample 2-1, the width of each slit portion was formed to be 2 mm. In Sample 2-2, as illustrated in FIG. 4, three slits each having a width of 1.6 mm were formed at both lateral sides of the signal wiring. In Sample 2-3, the width of the slit portion was formed to be 3.2 mm.

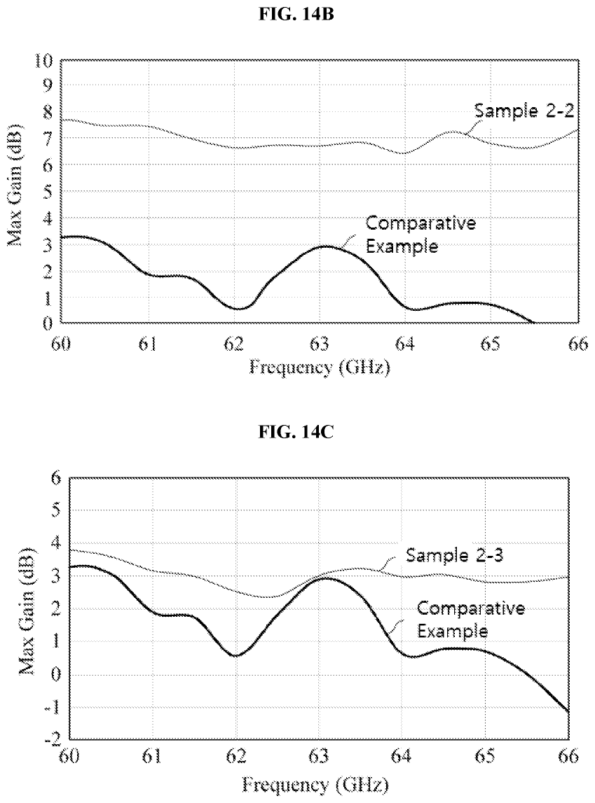

FIGS. 14A to 14C are graphs showing changes of an antenna gain according to modification of a slit portion. In Comparative Example shown in FIGS. 14A to 14C, a sample in which no slit portion was formed in the conductive layer was used.

Referring to FIGS. 14A to 14C, in Sample 2-1, the antenna gain significantly increased according to the formation of the slit portion, and the antenna gain additionally increased in Sample 2-2 in which a plurality of slit portions were formed,

In sample 2-3, as the slit portion width increased, the effect of increasing the antenna gain was lowered relatively to those from Samples 2-1 and 2-2.

What is claimed is:

1. A circuit board for an antenna, comprising:
a core layer having a first surface and a second surface facing each other;
a signal wiring disposed on the first surface of the core layer; and
a conductive layer disposed on the second surface of the core layer to cover the signal wiring in a plan view, the conductive layer having a slit portion formed around the signal wiring in the plan view.

2. The circuit board for an antenna according to claim 1, wherein the slit portion comprises a pair of slit portions formed at both lateral sides of a front end portion of the signal wiring in the plan view.

3. The circuit board for an antenna according to claim 2, wherein the conductive layer comprises a feeding ground portion disposed between the pair of slit portions to cover the front end portion of the signal wiring in the plan view.

4. The circuit board for an antenna according to claim 3, wherein a ratio of a width of the feeding ground portion to a line width of the signal wiring is from 10 to 18.

5. The circuit board for an antenna according to claim 3, wherein a ratio of a width of the feeding ground portion to a width of the slit portion is from 0.8 to 2.

6. The circuit board for an antenna according to claim 3, wherein the onductive layer has a first portion including the slit portion and the feeding ground portion, and a second portion having a solid plate shape.

7. The circuit board for an antenna according to claim 6, wherein the second portion covers a rear end portion of the signal wiring in the plan view.

8. The circuit board for an antenna according to claim 2, wherein a plurality of the slit portions are formed at each of both lateral sides of the front end portion of the signal wiring in the plan view.

9. The circuit board for an antenna according to claim 1, wherein the signal wiring comprises a plurality of signal wirings arranged in a width direction, and
the slit portion is formed between the plurality of signal wirings.

10. The circuit board for an antenna according to claim 9, wherein a plurality of the slit portions are formed between a pair of adjacent signal wirings among the plurality of signal wirings.

11. The circuit board for an antenna according to claim 1, wherein the signal wiring comprises a plurality of feeding portions and a merging portion coupling the feeding portions to each other, and
the slit portion is formed in each region between the feeding portions in the plan view.

12. An antenna package comprising:
an antenna unit comprising a radiator and a transmission line connected to the radiator; and
the circuit board for an antenna of claim 1 electrically connected to the antenna unit.

13. The antenna package according to claim 12, wherein the antenna unit further comprises a signal pad connected to an end portion of the transmission line,
a front end portion of the signal wiring of the circuit board for an antenna is bonded to the signal pad, and
the slit portion is formed around the front end portion of the signal wiring.

14. The antenna package according to claim 13, wherein the radiator has a mesh structure, and the signal pad has a solid structure.

15. An image display device comprising:
a display panel;
an antenna unit disposed on the display panel; and
the circuit board for an antenna of claim 1 electrically connected to the antenna unit.

16. The image display device according to claim 15, wherein a rear end portion without the slit portion of the circuit board for an antenna is bent below the display panel.
